(19) United States
(12) Patent Application Publication
(10) Pub. No.: US 2011/0058279 A1
(43) Pub. Date: Mar. 10, 2011

(54) OVERCOAT HAVING A LOW SILICON/CARBON RATIO

(76) Inventors: Eric FLINT, San Jose, CA (US); Joel Forrest, San Jose, CA (US); Yiping Hsiao, San Jose, CA (US); Yongjian Sun, Clifton, VA (US); Qi-Fan Xiao, San Jose, CA (US)

(21) Appl. No.: 12/533,463

(22) Filed: Jul. 31, 2009

(51) Int. Cl. G11B 5/60; C04B 35/593; C23C 14/32; C23C 14/06

(52) U.S. Cl. 360/235.1; 264/618; 204/192.38; G9B/5.229

(57) ABSTRACT

A slider for an information storage system. The slider comprising a single overcoat layer, wherein the layer is deposited onto an ABS of the slider by a filtered cathodic arc process, the layer having a Si/C ratio less than about 10% and a thickness of less than about 15 Å.

### FIELD

Embodiments of the present technology relates generally to the field of information storage systems.

### BACKGROUND

In a hard disk drive (HDD) environment, the magnetic spacing between a magnetic disk and the magnetic read/write head is becoming smaller and smaller. The smaller the magnetic spacing, the greater the density of data on the disk and the greater the signal strength between the head and the disk. The head typically has a protective overcoat that protects the head from corrosion and mechanical damage. One way to reduce the magnetic spacing is to reduce the thickness of the protective overcoat, which allows the read/write head to be disposed closer to the magnetic disk. However, a thin overcoat generally provides less protection for the head which can lead to failure of the HDD.

### BRIEF DESCRIPTION OF THE DRAWINGS

FIG. 1 illustrates an example of a HDD, in accordance with an embodiment of the present invention.

FIG. 2, illustrates a slider, in accordance with an embodiment of the present invention.

FIG. 3 illustrates an example of a flow chart of a method for manufacturing an overcoat layer, in accordance with an embodiment of the present invention.

FIG. 4 illustrates an example of a flow chart of a method for manufacturing a cathode, in accordance with an embodiment of the present invention.

The drawings referred to in this description should be understood as not being drawn to scale except if specifically noted.

### DESCRIPTION OF EMBODIMENTS

Reference will now be made in detail to embodiments of the present technology, examples of which are illustrated in the accompanying drawings. While the technology will be described in conjunction with various embodiment(s), it will be understood that they are not intended to limit the present technology to these embodiments. On the contrary, the present technology is intended to cover alternatives, modifications and equivalents, which may be included within the spirit and scope of the various embodiments as defined by the appended claims.

Furthermore, in the following description of embodiments, numerous specific details are set forth in order to provide a thorough understanding of the present technology. However, the present technology may be practiced without these specific details. In other instances, well known methods, procedures, components, and circuits have not been described in detail as not to unnecessarily obscure aspects of the present embodiments.

Magnetic spacing or fly height is critically important in a HDD. The signal strength between the slider and the disk is exponentially related to the spacing. The lower the spacing, the greater the density of data that can be provided on the disk and the stronger the magnetic signal between the slider and the disk. One way to reduce the magnetic spacing is to reduce the thickness of the protective overcoat layer on the slider. The thinner the protective layer on the slider, the closer the slider can fly with respect to the disk without touching the disk during the read/write process of the HDD. However, as the protective overcoat becomes thinner, the overcoat material approaches its physical and process limits and consequently provides less mechanical and chemical protection to the slider.

Typically, in a HOD, a slider has a protective overcoat having at least two distinct deposited layers. At least one layer is an adhesion layer which is typically comprised of silicon (Si) or a silicon nitride (SiNₓ). Another layer is a carbon (C) layer which is deposited over the adhesion layer to protect the slider from mechanical and chemical damages. Without the adhesion layer, the deposited carbon layer does not sufficiently adhere to the slider.

The mechanical protection of the overcoat is to protect the slider and its components from mechanical damages. Mechanical protection can be but is not limited to protecting the slider from damage when contaminants in the HDD collide with the slider or protecting the slider from damage if the slider makes physical contact with other components within the HDD. The chemical protection of the overcoat can be but is not limited to the protection of corrosion. For example, humidity is often present in a HDD and the humidity can corrode the slider and/or its components if the slider is not adequately protected. Mechanical and/or chemical damages to the slider often cause drive failure.

An overcoat thickness of 15 angstroms (Å) or less can create a challenge to provide sufficient protection to the slider. From a materials science point of view, the Si or SiNₓ adhesive layer must have a thickness of at least 5 Å to provide a sufficient bond between the slider material and carbon. The slider material can be but is not limited to the materials of the air bearing surface (ABS), pole material, or sensor material. As the Si or SiNₓ thickness approaches 5 Å, the thin film no longer remains continuous. Additionally, a mechanically robust carbon thin film, such as filtered cathodic carbon (Ta—C), has an unfavorably high pinhole density at around a thickness of 10 Å. The higher the pinhole density in the carbon layer, the higher the volume of air and other contaminants that are able to reach the slider and potentially cause corrosion to the slider.

Moreover, it is extremely difficult to control the processes that control the thickness of the deposited layers onto the slider, especially at such small thicknesses. For example, the slider overcoat can have a design requirement that its thickness is to be 15 Å, with the adhesive layer having a thickness of 5 Å and the carbon layer having a thickness of 10 Å. If, the control process for the deposition of the adhesion layer deposits an adhesion layer with a thickness of 6 Å and the subsequent carbon layer is the required 10 Å, the magnetic spacing is subsequently larger than required, which can cause drive failure. Similarly, if the adhesive layer is deposited at the required thickness of 5 Å and the carbon layer is 11 Å in thickness, the magnetic spacing will be larger than designed which can cause drive failure.

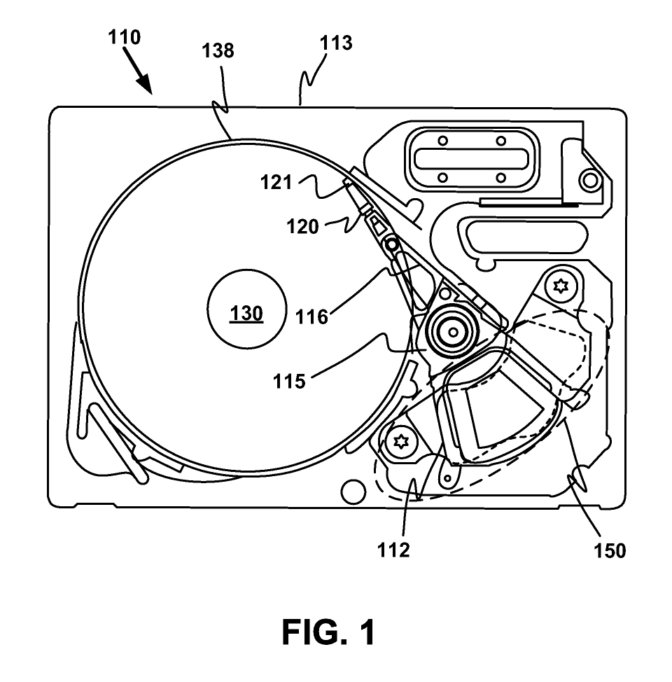

With reference now to FIG. 1, a schematic drawing of one embodiment of an information storage system including a magnetic hard disk file or HDD 110 for a computer system is shown, although only one head and one disk surface combination are shown. What is described herein for one head-disk combination is also applicable to multiple head-disk combinations. In other words, the present technology is independent of the number of head-disk combinations.

In general, HDD 110 has an outer sealed housing 113 usually including a base portion (shown) and a top or cover (not shown). In one embodiment, housing 113 contains a disk pack having at least one media or magnetic disk 138. The disk pack (as represented by disk 138) defines an axis of rotation and a radial direction relative to the axis in which the disk pack is rotatable.

A spindle motor assembly having a central drive hub 130 operates as the axis and rotates the disk 138 or disks of the disk pack in the radial direction relative to housing 113. An actuator assembly 115 includes one or more actuator arms 116. When a number of actuator arms 116 are present, they are usually represented in the form of a comb that is movably or pivotally mounted to base/housing 113. A controller 150 is also mounted to base 113 for selectively moving the actuator arms 116 relative to the disk 138. Actuator assembly 115 may be coupled with a connector assembly, such as a flex cable to convey data between arm electronics and a host system, such as a computer, wherein HDD 110 resides.

In one embodiment, each actuator arm 116 has extending from it at least one cantilevered integrated lead suspension (ILS) 120. The ILS 120 may be any form of lead suspension that can be used in a data access storage device. The level of integration containing the slider 121, ILS 120, and read/write head is called the Head Gimbal Assembly (HGA).

The ILS 120 has a spring-like quality, which biases or presses the air-bearing surface (ABS) of slider 121 against disk 138 to cause slider 121 to fly at a precise distance from disk 138. ILS 120 has a hinge area that provides for the spring-like quality, and a flexing cable-type interconnect that supports read and write traces and electrical connections through the hinge area. A voice coil 112, free to move within a conventional voice coil motor magnet assembly is also mounted to actuator arms 116 opposite the head gimbal assemblies. Movement of the actuator assembly 115 by controller 150 causes the head gimbal assembly to move along radial arcs across tracks on the surface of disk 138.

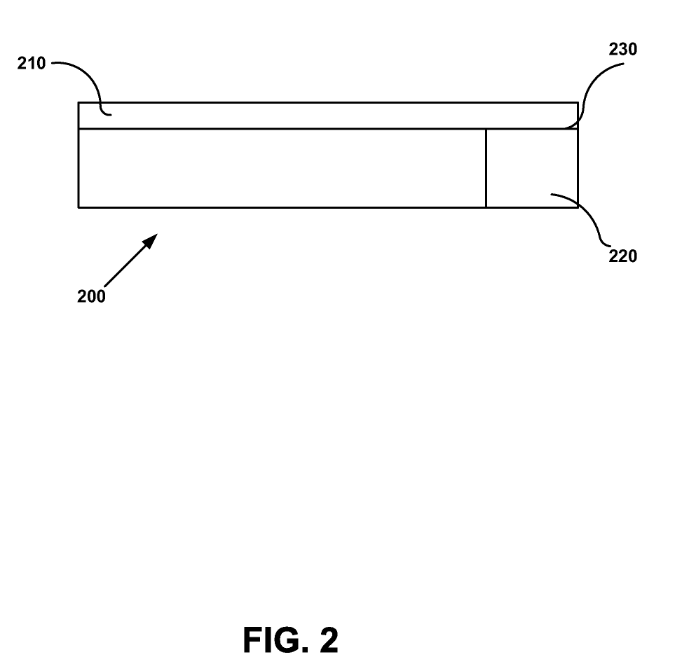

FIG. 2 illustrates a slider 200 having single overcoat layer 210, wherein the layer is deposited onto an ABS 230 of the slider by a filtered cathodic arc process. In one embodiment, the slider 200 has a magnetic read/write head 220.

It can be appreciated that the slider can have a variety of components and physical features to properly read and/or write information to the magnetic disk. In another embodiment, layer 210 covers the entire slider 200. It can be appreciated that the layer 210 covers the areas of the slider that are susceptible to mechanical and/or chemical damages and prevents the HDD from failure due to mechanical and/or chemical damages

in one embodiment, the layer 210 is a filtered cathodic silicon carbide (FCA-SiCₓ). In another embodiment, the layer is a filtered cathodic silicon carbonitride (FCA-SiNₓC_{y}). In one embodiment, the thickness of the layer 210 is less than about 15 Å. It can be appreciated that the a design requirement for the layer thickness 210 to be 15 Å is within manufacturing and engineering tolerances.

The filtered arc process that produces a 15 Å overcoat of a filtered cathodic silicon carbide and the filtered cathodic silicon carbonitride is advantageous over a process that creates a 5 Å Si layer and a 10 Å C layer. The process and thickness control of the filtered cathodic arc process is simpler because it eliminates the Si adhesion layer. The Si adhesion layer is solely for adhesion of the carbon layer to the slider and does not protect the slider from mechanical and/or chemical damages. If the adhesion layer is removed from the overcoat process, the magnetic spacing can become smaller which is advantageous, as described above.

Moreover, if the carbon layer is too thin, which generally causes a high pinhole density, the silicon can become oxidized. The resulting silicon dioxide increases in thickness compared to the initial silicon layer thickness. It can be appreciated that the silicon dioxide can almost double in thickness compared to the initial silicon layer thickness. Consequently, the increased thickness of the silicon dioxide changes the required magnetic spacing which can result in drive failure.

The FCA-SiCₓ and FCA-SiNₓC_{y} also have good mechanical robustness and adhesion to the slider 200. The FCA-SiCₓ and FCA-SiNₓC_{y} layers have a low Si/C ratio. A low Si/C ratio is desired for a higher sp3 phase for carbon and consequently a higher sp3 in the overcoat layer. In other words, if there is low silicon concentration, then there is a high diamond bond. A low Si/C ratio also provides for less Si to diffuse out or oxygen to diffuse through the carbon and form a native SiOₓ layer on top of the overcoat surface, which then defeats the magnetic spacing requirement. In one embodiment, layer 210 has a Si/C ratio less than about 10%. Ideally, it is desirable to have the Si/C ratio as low as possible as long as there are no adhesion problems.

The amount of silicon in an overcoat layer deposited by a cathodic arc process is related to the amount of silicon in the cathode used in the cathodic arc process. Typically, Si is mixed with graphite powder and the mixture is hot pressed to form the cathode. During the cathodic arc process, the Si in the cathode melts first and consequently the deposited layer has a high Si concentration. In particular, a deposited layer usually has a higher Si/C ratio than the Si/C ratio of the cathode. The difference sometimes depends on the cathodic arc process, such as but not limited to arc voltage, current, Ar flow and the like. Often the difference is attributed to the much lower melting point of Si (1414 C) compared to graphite (3550 C). Comparatively, the melting temperature for SiC is 2825 C. The disassociation point of Si₃N₄ is about 195° C. which is higher than Si by 500 C.

It can be appreciated that the higher Si/C ratio in the deposited layer from a Si/graphite cathode can be attributed to the Si grains being pulled out through arc melting and then being evaporated. The resulting deposited layer has a very rough and loose surface. A cathode having a 5% Si/graphite composition can have a resultant deposited layer having a 30% Si/C ratio.

In one embodiment, the cathode in a cathodic arc process is comprised of a SiC and graphite mixture. In another embodiment, the cathode is comprised of a Si₃N₄ and graphite mixture. In another embodiment, the cathode is hot pressed. In a further embodiment, the cathode is formed by a hot isostatic pressure (HIP) process. It can be appreciated that in various embodiments, the percentage of SiC or Si₃N₄ in the cathode composition is less than 10%. It can also be appreciated that the deposited layer having Si/C ratio of less than 10% is otherwise not achievable by other known techniques such as filtered cathodic arc process on a hot processed or HIP cathode made from Si and graphite powders with or without N₂.

In one embodiment, a Si/C ratio in a deposited layer is about 8% from a 5% SiC/graphite cathode. In another embodiment, the surface oxygen is dramatically lower for FCA-SiCₓ film made from the 5% SiC/graphite cathode than that from a 5% Si/graphite cathode.

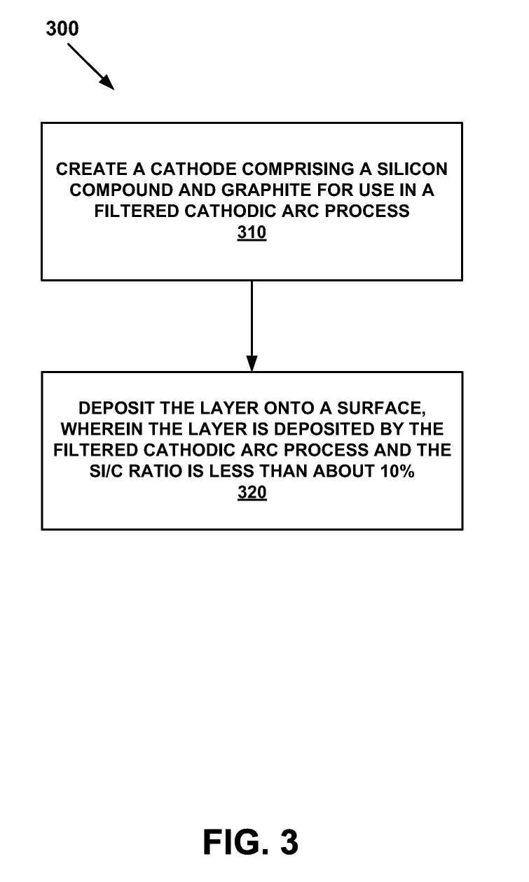

FIG. 3 depicts a flow chart of a method 300 for manufacturing a low Si/C ratio overcoat layer. In step 310 of method 300, a cathode is created comprising a silicon compound and graphite for use in a filtered cathodic arc process. In one embodiment, the compound is SiC. In another embodiment, the silicon compound is Si₃N₄. In another embodiment, the cathode is created by utilizing a hot press process. In a further embodiment, the cathode is created by utilizing a hot isostatic pressure process.

In step 320, a protective layer is deposited onto a surface, wherein the layer is deposited by a filtered cathodic arc process and the Si/C ratio is less than about 10%. In one embodiment, the layer is a filtered cathodic silicon carbide. In another embodiment, the layer is a filtered cathodic silicon carbonitride. In another embodiment, the layer has a thickness of less than about 15 Å. In a further embodiment, the layer is comprised of substantially sp3 bonds. In another embodiment, the Si/C ratio of the layer is about 8%, when the layer is deposited from a cathode comprising SiC and graphite, wherein the cathode is 5% SiC.

In one embodiment, method 300 does not require an intermediary adhesive layer. It can be appreciated that the intermediary adhesive layer is Si. In one embodiment, the surface is a surface on a slider. It can be appreciated that the surface can be any surface that can be mechanically and/or chemically protected by a single layer of either: FCA-SiCₓ or FCA-SiNₓC_{y}.

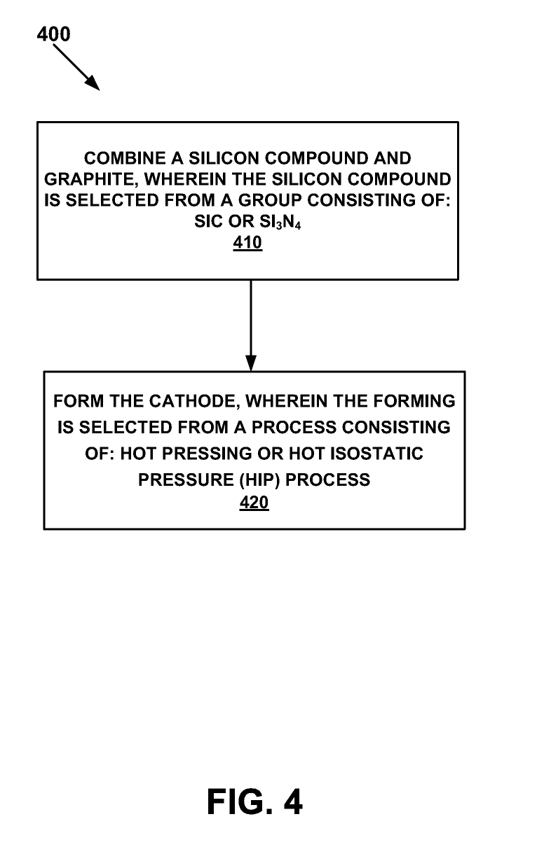

FIG. 4 depicts a flow chart of a method 400 for manufacturing a cathode for use in a filtered cathodic arc process to control the Si/C ratio in a deposited layer to less than about 10%, the deposited layer selected from a group consisting of: filtered cathodic silicon carbide or filtered cathodic silicon carbonitride. In step 410 of method 400, a silicon compound and graphite are combined, wherein the silicon compound is selected from a group consisting of: SiC or Si₃N₄.

In step 420, the cathode is formed, wherein the forming of the cathode is selected from a process consisting of: hot pressing or hot isostatic pressure process. It can be appreciated that the cathode can be utilized in various cathodic arc processes.

Although the subject matter has been described in a language specific to structural features and/or methodological acts, it is to be understood that the subject matter defined in the appended claims is not necessarily limited to the specific features or acts described above. Rather, the specific features and acts described above are disclosed as example forms of implementing the claims.

1. A slider device for an information storage system, said slider device comprising:
a slider; and
a single overcoat layer, wherein said layer is deposited onto an air-bearing surface (ABS) of said slider by a filtered cathodic arc process and said layer having a Si/C ratio less than about 10%.

2. The slider device of claim 1, wherein said layer is a filtered cathodic silicon carbide.

3. The slider device of claim 1, wherein said layer is a filtered cathodic silicon carbonitride.

4. The slider device of claim 1, wherein said layer is formed from a cathode comprising SiC and graphite.

5. The slider device of claim 1, wherein said layer is formed from a cathode comprising Si₃N₄ and graphite.

6. The slider device of claim 1, wherein said layer comprising substantially sp3 bonds.

7. The slider device of claim 1, wherein said slider does not require an adhesive layer between said single overcoat layer and said slider.

8. The slider device of claim 1, wherein said layer protects said slider from mechanical damages and chemically protects said slider from corrosion.

9. The slider device of claim 1, wherein said slider overcoat layer having a thickness of less than about 15 Å.

10. A method for manufacturing a low Si/C ratio overcoat layer, wherein said method comprises:
creating a cathode comprising a silicon compound and graphite for use in a filtered cathodic arc process; and
depositing said layer onto a surface, wherein said layer is deposited by said filtered cathodic arc process and said Si/C ratio is less than about 10% and said layer having a thickness of less than about 15 Å.

11. The method of claim 9, wherein said layer is a filtered cathodic silicon carbide.

12. The method of claim 9, wherein said layer is a filtered cathodic silicon carbonitride.

13. The method of claim 9, wherein said creating a cathode further comprises:
utilizing a hot press process.

14. The method of claim 9, wherein said creating a cathode further comprises:
utilizing a hot isostatic pressure process.

15. The method of claim 9, wherein said silicon compound is SiC.

16. The method of claim 9, wherein said silicon compound is Si₃N₄.

17. The method of claim 9, wherein said Si/C ratio is about 8% from a cathode comprising SiC and graphite, wherein said cathode is 5% SiC.

18. The method of claim 9, wherein said method further comprises:
said layer comprising substantially sp3 bonds.

19. The method of claim 9, wherein said method further comprises:
not requiring an intermediary adhesive layer.

20. A method for manufacturing a cathode for use in a filtered cathodic arc process to control the Si/C ratio in a deposited layer to less than about 10%, said deposited layer having a thickness of less than about 15 Å and selected from a group consisting of: filtered cathodic silicon carbide or filtered cathodic silicon carbonitride, wherein said method comprises:
combining a silicon compound and graphite, wherein said silicon compound is selected from a group consisting of: SiC or Si₃N₄; and
forming said cathode, wherein said forming is selected from a process consisting of: hot pressing or hot isostatic pressure (HIP) process.
